(19) United States
(12) Patent Application Publication
(10) Pub. No.: US 2016/0234982 A1
(43) Pub. Date: Aug. 11, 2016

(54) HOUSING AND CONTROL UNIT HAVING A HOUSING

(71) Applicant: Robert Bosch GmbH, Stuttgart (DE)

(72) Inventors: Gerold Kohlberger, Rettenberg-Freidorf (DE); Martin Winkler, Sonthofen (DE); Stephan Knackert, Haldenwang (DE); Bernd Lutz, Kempten (DE)

(21) Appl. No.: 15/014,326

(22) Filed: Feb. 3, 2016

(30) Foreign Application Priority Data
Feb. 10, 2015 (DE) 102015202316.8

(51) Int. Cl. H05K 9/00; H05K 5/00

(52) U.S. Cl. CPC H05K 9/0084; H05K 5/0047

(57) ABSTRACT

A housing (1) is described, which is designed for accommodating an electric and/or electronic circuit (2), the housing (1) having at least one first (4) and a second (5) housing part corresponding to the first, at least one metallic layer (8) being disposed in the area of at least one inner side of the housing parts (4, 5), and the metallic layer (8) having at least one electric contact surface (11) designed to contact the electric and/or electronic circuit (2).

The present invention relates to a housing designed to accommodate an electric and/or electronic circuit and a control unit for a motor vehicle having a housing.

### BACKGROUND INFORMATION

Currently, housings for circuits, such as control units for example, which are sensitive with respect to electromagnetic compatibility (EMC), are normally constructed from metal housings. These metal housings provide the mechanical protection, the accommodation of the circuit as well as the discharge and/or shielding of the EMC radiation. The metal housings may be made up of an aluminum cast or of metallically filled plastics.

DE 10 2010 003 666 A1 discloses a housing for a camera of a vehicle. The camera housing has at least one accommodating surface for a light-deflecting device, such as a mirror, which is designed to deflect light from at least one additional sensing region to the camera optics.

These known housings can be expensive and heavy depending on the selection of materials.

### DISCLOSURE OF THE INVENTION

The present invention provides a housing designed for accommodating an electric and/or electronic circuit, the housing having at least a first and a second housing part corresponding to the first, at least one metallic layer being disposed in the area of at least one inner side of the housing parts, and the metallic layer having at least one electric contact surface designed to contact the electric and/or electronic circuit.

The housing according to the present invention separates the function of the EMC protection from the mechanical function of the housing such as for example protection or accommodation of the circuit. This allows for a cost-effective housing and simple assembly. In addition, the manufacture may be performed in in-line fashion. The housing is furthermore optimized in terms of weight, which is important especially in the case of a high installation location in a vehicle. Separating the EMC functionality from the housing provides great flexibility. Thus it is possible for example to scale the metallic layer in accordance with EMC requirements or as a function of the utilized circuits or the environment of the housing.

The first and second housing parts may be made of a non-metallic material such as plastic, for example. Since the metallic layer already performs the electric shielding and/or discharge, it is no longer necessary for the housing parts to provide this function such that the housing parts or, in other words, the basic housing may be manufactured from material optimized in terms of cost and weight.

The metallic layer may be a metallic foil. A metallic foil is cost-effective and easy to procure and is also easy to process. A foil of this type may nevertheless satisfy the requirements of an EMC protection. The term foil comprises in this case a very thin metal sheet.

The metallic layer may have a thickness between 0.02 and 0.7 mm, preferably between 0.1 and 0.4 mm, most preferably 0.2 mm. The thickness may be selected, on the on hand, under electric or electromagnetic aspects. The thickness is in that case selected on the basis of parameters such as the fields and/or currents to be discharged. On the other hand, the thickness of the metallic layer may be selected under mechanical aspects or with a view to the manufacture. In this regard, it matters for example whether the metallic layer is to be relatively stiff or whether it should be flexible.

The metallic layer may be deep-drawn and may have a contour adapted to the housing part. Deep-drawing makes it possible to give the metallic layer a dimensionally stable structure so that it may be readily inserted into the housing part with its adapted contour, which allows for a simple manufacture. The metallic layer may correspond to the housing part in its contour or may be adapted at least to such an extent that the metallic layer on the one hand fits into the housing part and on the other hand surrounds the circuit. This results in a freedom of design regarding weight optimization, optimization of manufacture and/or optimization of the EMC properties.

The metallic layer may be applied at least on an area of the inner side of the housing part. The metallic layer may be bonded, clamped or welded, for example. This is preferably done if the metallic layer is not dimensionally stable.

For each of the housing parts, a metallic layer may be provided, and the metallic layers may be connected to one another in an electrically conductive manner at least point-wise, preferably along at least one shared edge. In this manner, even multiple metallic layers or metallic layers divided into multiple component parts form a common protective cage for the circuit. This system improves the EMC properties of the housing further.

The metallic layer may be a metallic foil of one piece, and its dimensions may be designed to enclose the electric and/or electronic circuit. Thus, for example, it is possible to use a thin metallic foil made of one piece, on which the circuit is placed, and subsequently the second half of the foil is folded around the electronic circuit such that the latter is enclosed by the metallic foil. Subsequently, the foil may be welded at the edge or at the edges such that the circuit is completely enclosed by the foil.

A housing part and the metallic layer may have corresponding openings, and another metallic layer may be provided for closing the opening. Such an opening for example may be a terminal opening for example for a cable or a plug connector or a sensor opening such as an optical path or lens for a camera. The additional metallic layer may then be a plate for example.

The control unit of the present invention for a motor vehicle includes a housing as described above, an electric and/or electronic circuit of the control unit being situated in the housing and the electric and/or electronic circuit being in electric contact with the at least one electric contact surface of the electric layer. The same advantages and modifications apply as were described above. The control unit may be for example a control unit for a camera on the interior mirror of a vehicle. Often, a GPS (global positioning system) receiver is situated in the immediate vicinity of the control unit in the roof of the vehicle. The metallic layer is advantageously provided in order to protect both the camera or the electronics of the camera as well as the GPS receiver against the influence of electromagnetic radiation.

### DRAWINGS

Exemplary embodiments of the present invention are explained in greater detail with reference to the drawings and the following description. The figures show:

FIG. 1 an exploded representation of the housing according to the present invention;

FIG. 2 a sectional view through the housing;

FIG. 3 a top view on the housing including a circuit; and

FIG. 4 a top view on the housing including a metallic layer.

### SPECIFIC EMBODIMENTS OF THE INVENTION

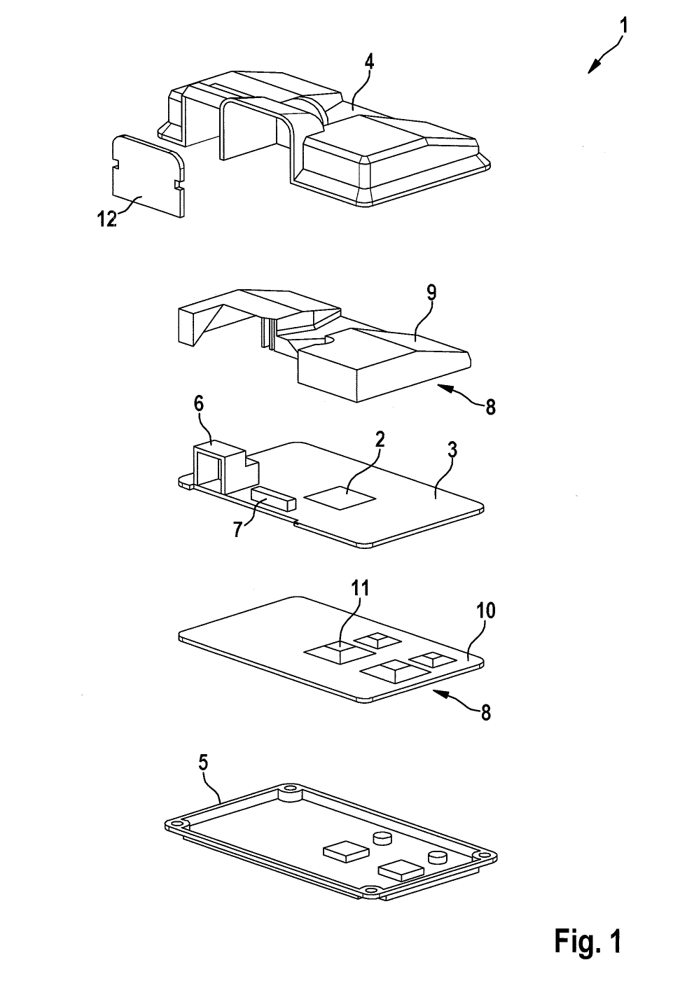

FIG. 1 shows a housing 1, which surrounds an electric and/or electronic circuit 2, which is here situated on a circuit board 3. Housing (1) has a first housing part 4 and a second housing part 5.

For reasons of clarity, circuit 2 is shown only schematically. Circuit 2 may be designed for signal processing, for signal calculation, for controlling additional components and/or for performing calculations. Circuit board 3, also called a conductor board or PCB (printed circuit board), furthermore includes a terminal 3, for example for receiving a plug connector, for supplying energy and/or signals. In addition, a plug-connector strip 7 is optionally attached on circuit board 3, to which additional elements, such as additional circuits and/or sensors for example, may be connected. Terminal 6 and plug-connector strip 7 are connected to circuit 2. Instead of [being plugged into] a plug-connector strip, a sensor, such as a camera for example, may also be situated directly on circuit board 3.

First and second housing parts 4 and 5 are manufactured from a cost-effective plastic, which ensures sufficient stability for housing 1 and offers impermeability with respect to dust and/or water, depending on the application. For reasons of modularity, for example, it is possible to use more than two housing parts. The two housing parts 4 and 5 correspond to each other, that is to say, they may be set one upon the other and be connected to each other using suitable plastic connecting methods such as for example heat staking, welding, crimping, screwing, bonding, laser-tight welding etc. For reasons of heat dissipation for example, one of the two housing parts 4 or 5 may have a metallic structure. This will normally be the housing part that is on top in the installed state of housing 1.

Housing 1 further includes two metallic layers 8. One metallic layer 8 is developed as a deep-drawn insert 9, which is manufactured from a metal such as for example aluminum, steel, copper etc. Insert 9 has a thickness between 0.1 and 0.4 mm, preferably 0.2 mm. Insert 9 has a contour corresponding at least essentially to the contour of first housing part 4. Insert 9 is situated between first housing part 4 and circuit board 3 having circuit 2.

Second metallic layer 8 is made up of a bottom plate 10. Bottom plate 10 is made of a metal, such as aluminum, steel, copper or the like, and is stamped or embossed. Bottom plate 10 is located between circuit board 3 and second housing part 5. Bottom plate 10 has at least one electric contact surface, which is in electric contact with circuit 2 in the assembled state of the housing or control unit. Contact surface 11 may either be in contact directly with circuit 2, for example by abutment, or electrical contact surface 11 may be indirectly in contact with circuit 2, for example via a line on circuit board 3. Alternatively or in addition to bottom plate 10, insert 9 may have one or more contact surfaces.

Metallic layer 8 furthermore includes a plate 12, which is likewise made of metal, for example of aluminum, steel, copper or the like, and which may be stamped. Plate 12 closes an opening in first housing part 4, which is situated in the area of plug-connector strip 7.

Metallic layer 8 encloses circuit board 3 having circuit 2, if possible completely, but at least in large areas, in order to protect circuit 2 against EMC radiation, which is produced outside of housing 1, and to protect the surroundings of housing 1 against EMC radiation that is produced by circuit 2 and/or circuit board 3. Openings in the metallic layer, such as for terminal 6 for example, may be shielded individually. Thus, terminal 6, for example, may have a metallic housing, which attaches to insert 9. The opening in first housing part 4 is closed by plate 12. Additional openings of the housing, which are required for a sensor for example, cannot be closed by metallic layer 8. However, if possible, this opening may be situated so as to lie in angled regions of metallic layer 8 such that even in this region there may be, albeit lesser, discharge of and/or shielding [against] the EMC radiation.

Housing 1 may be used for example as the housing of a camera in or on an interior mirror of a vehicle. Usually, a GPS receiver is located in the immediate vicinity of the camera housing. Housing 1 protects both the camera and its electronics as well as the GPS receiver against unwanted EMC interferences.

The manufacture or assembly of housing 1 will now be described. The basic housing made up of first housing part 4 and second housing part 5 is manufactured from a cost-optimized and weight-optimized plastic. Deep-drawn insert 9 of metallic layer 8 is inserted into first housing part 4. Insert 9 may be fastened mechanically, for example welded, clamped or bonded. On the other hand, it may be mounted in first housing part 4 by its inherent stability alone. Bottom plate 10 may be fastened in second housing part 5 by the same methods.

Subsequently, the equipped conductor board or circuit board 3 is mounted in second housing part 5. The fastening may occur for example by heat staking, screwing or bonding. Circuit board 3 or circuit 2 is brought into contact with electric contact surface 11 of bottom plate 10. This may be a separate work step or it may already occur during the assembly of circuit board 3. Now the two housing parts 4 and 5 are connected to each other using suitable plastic connecting methods such as heat staking, welding, crimping, screwing, bonding, laser-tight welding etc. Depending on the desired tightness of housing 1, a seal may be inserted between the two housing parts 4 and 5. It is not necessary for the steps described above to be performed in this sequence.

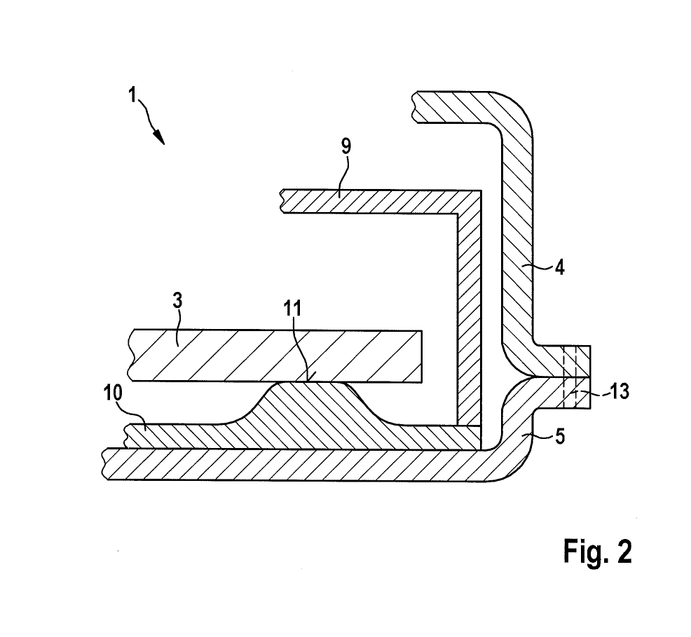

FIG. 2 shows a sectional view of an area of the assembled housing 1. An outer area of housing 1 is shown. It may be seen that the two housing parts 4 and 5 correspond to each other, that is to say that they form an at least largely enclosed interior. Here the two housing parts 4 and 5 may be screwed or dowelled to each other via through holes 13. Bottom plate 10 is situated on an inner side of second housing part 5. Bottom plate 10 may in this instance rest in a planar manner on the inner side of second housing part 5 or may be spaced apart from it by a spacer for example. Insert 9 is in contact with bottom plate 10 so that insert 9 and bottom plate 10 form a conductive cage around circuit board 3 having circuit 2. For this purpose, insert 9 and bottom plate 10 are in contact over a large area. These two elements abut against each other over a large area, as shown here, along at least one shared edge. Furthermore, insert 9 and bottom plate 10 are in electrical contact via electrical contact surface 1 with circuit board 3 and/or circuit 12 in order thus to discharge or shield [against] EMC radiation.

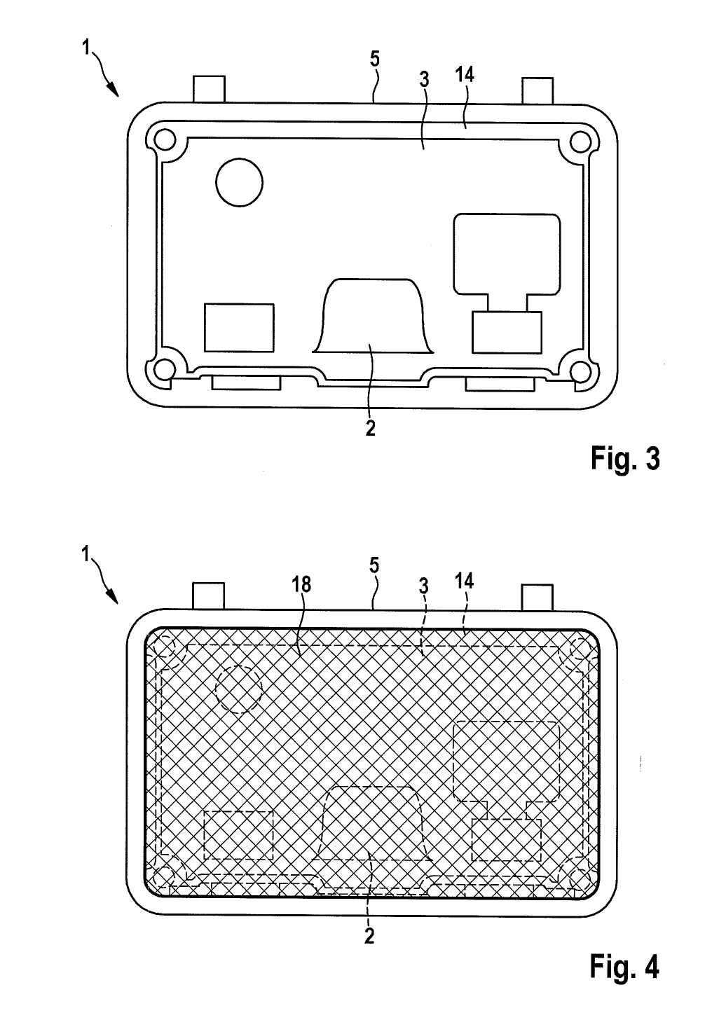

Another exemplary embodiment of housing 1 is shown in FIGS. 3 and 4. FIG. 3 shows a top view of second housing part 5 with an already mounted circuit board 3 and schematically represented electric/electronic circuit 2. At least on one side, circuit board 3 has a metal-plated edge 14, preferably circumferentially. In this case, the metallic layer is developed in one piece as metallic foil 18 (see FIG. 4).

In FIG. 3, one-piece metallic foil 18 or approximately half of this foil is situated below circuit board 3. The remaining half is not shown in FIG. 3 for reasons of clarity. This second half of one-piece metallic foil 18 protrudes from second housing part 5 and is folded over along metal-plated edge 14 so that one-piece metallic foil 18 covers the top side of circuit board 3 having circuit 2. This state is shown in FIG. 4. There, the top side of circuit board 3 and thus of circuit 2 is covered by metallic foil 18 and is thus protected by [sic; against] radiation. Via the contact of one-piece metallic foil 18 with metal-plated edge 14 of circuit board 3, the electrical connection is established between foil 18 and circuit 2. Metallic foil 18 may be fastened, for example bonded, circumferentially on the outside edges of circuit board 3. The foil may have a thickness between 0.02 and 0.1 mm.

What is claimed is:

1. A housing set up for accommodating an electric and/or electronic circuit (2),
the housing (1) including at least one first (4) and a corresponding second (5) housing part,
wherein at least one metallic layer (8) is situated in the area of at least one inner side of the housing parts (4, 5), and the metallic layer (8) has at least one electric contact area (11) for contact with the electric and/or electronic circuit (2).

2. The housing as recited in claim 1,
wherein the first (4) and the second (5) housing parts are made of a nonmetallic material.

3. The housing as recited in claim 1 or 2,
wherein the metallic layer (18) is a metallic foil.

4. The housing as recited in one of claims 1 through 3, wherein the metallic layer has a thickness between 0.02 and 0.7 millimeters, preferably between 0.1 and 0.4 millimeters, most preferably of 0.2 millimeters.

5. The housing as recited in one of claims 1 through 4, wherein the metallic layer is deep-drawn and has a contour adapted to the housing part (4, 5).

6. The housing as recited in one of claims 1 through 5, wherein the metallic layer is applied at least on one area of the inner side of the housing part (4, 5).

7. The housing as recited in one of claims 1 through 6,
wherein for each of the housing parts (4, 5) a metallic layer (9, 10) is provided and
wherein the metallic layers (9, 10) are connected to each other in electrically conductive fashion at least point-wise, preferably along at least one shared edge.

8. The housing as recited in one of claims 1 through 7, wherein the metallic layer is a one-piece metallic foil (18) whose dimensions are designed to enclose the electric and/or electronic circuit (2).

9. The housing as recited in one of claims 1 through 8, wherein a housing part (4) and the metallic layer have corresponding openings, and wherein another metallic layer (12) is provided for closing the opening.

10. A control unit for a motor vehicle having a housing as recited in one of claims 1 through 9,
wherein an electric and/or electronic circuit (2) of the control unit is situated in the housing (1) and
wherein the electric and/or electronic circuit (2) is in electric contact with the at least one electric contact surface (1) of the electrical layer (8).
